(19) United States
(12) Patent Application Publication
(10) Pub. No.: US 2007/0040220 A1
(43) Pub. Date: Feb. 22, 2007

(54) AN ELECTROSTATIC DISCHARGE CIRCUIT

(75) Inventors: Te-Wei Chen, Chupei City, Hsinchu County (TW); Li-Chiu Weng, Hsinchu (TW)

Correspondence Address: PAI PATENT & TRADEMARK LAW FIRM, 1001 FOURTH AVENUE, SUITE 3200, SEATTLE, WA, 98154, US

(73) Assignee: SILICONMOTION INC., Jhubei City, Hsinchu County (TW)

(21) Appl. No.: 11/163,772

(22) Filed: Oct. 29, 2005

(30) Foreign Application Priority Data
Aug. 17, 2005 (TW) 94128101

(51) Int. Cl. H01L 23/62

(52) U.S. Cl. 257/355

(57) ABSTRACT

An electrostatic discharge circuit includes at least an electrostatic discharge zener diode, an NMOS transistor, and a PMOS transistor. The electrostatic discharge zener diode is used for lowering the breakdown voltage and making the electrical current discharge through it, thereby preventing the circuit device from burning out and greatly enhancing the function of electrostatic discharge protection.

### CROSS-REFERENCE TO RELATED APPLICATIONS

The present application is based on, and claims priority from, Taiwan Application Serial Number 94128101, filed Aug. 17, 2005, the disclosure of which is hereby incorporated by reference herein in its entirety.

### BACKGROUND OF THE INVENTION

1. Field of Invention

The invention relates to an electrostatic discharge (ESD) circuit and, in particular, to an ESD circuit using the ESD zener diode.

2. Related Art

In daily life, separating different materials from or rubbing different materials against each other can produce static electricity. For example, squeezing, cutting, moving, churning, and filtering in production processes; and walking, standing, and taking off clothes in daily life all produce static electricity. One therefore may say that static electricity is everywhere. Even our bodies and surroundings may carry a lot of electrostatic voltage, up to thousands or even tens of thousands of volts. Such static electricity may not have great influence on human bodies, but it may cause damage to some devices that are sensitive to electrostatic effects so that they partially or totally lose their normal functions. Consequently, electrostatic discharge (ESD) has received much attention in recent years.

FIG. 1A depicts a diagram of a conventional ESD circuit 100 currently popular on the market. The ESD circuit 100 includes an NMOS transistor 102, a PMOS transistor 101, and a diode 103. The structure of this conventional ESD circuit is as follows:

The source of the PMOS transistor 101 is coupled to a high voltage Vcc. The drain of the NMOS transistor 102 is simultaneously coupled to the drain of the PMOS transistor 101, the circuit device terminal 104, and the cathode of the diode 103. The anode of the diode 103 is coupled to the ground. When an electrostatic voltage is produced, the diode 103 breaks down to permit the electrical current to flow out.

FIGS. 1B and 1C show two examples of forming the diode 103 in FIG. 1A. In the diode 103 of FIG. 1B, a high-concentration doping region is used for subsequent connections. For example, the N+ doping region 120 is coupled to the circuit device terminal 104 of FIG. 1A. The P+ doping region 110 is coupled to the ground in FIG. 1A. The N well 130 and the P well 140 form an N-P diode.

In the other example of the diode 103 shown in FIG. 1C, the N+ doping region 160 is coupled to the circuit device terminal 104 in FIG. 1A. The P+ doping region 150 is coupled to the ground in FIG. 1A. The N+ doping region 160 and the P well 170 form an N+-P diode.

Currently, the usual ESD circuits use either of the above two types of diodes. However, there is a very serious problem with these ESD circuits. That is, the breakdown voltages of these ESD circuits are about 8-10 V. In other words, they cannot provide any protection for circuits operating below 8 V.

Therefore, it is very important to provide an ESD circuit operating at a lower voltage.

### SUMMARY OF THE INVENTION

An objective of the invention is to provide an ESD circuit for improving ESD protection.

Another objective of the invention is to provide an ESD zener diode which can be used in an ESD circuit to lower its breakdown voltage, thus providing better ESD protection.

According to a preferred embodiment of the invention, the ESD circuit includes an NMOS transistor, a PMOS transistor, and an ESD zener diode. The ESD zener diode is used to decrease the breakdown voltage, so that the electrical current discharges through it, thereby preventing the circuit from burning out and also greatly enhancing the function of ESD protection.

### BRIEF DESCRIPTION OF THE DRAWINGS

These and other features, aspects and advantages of the invention will become apparent by reference to the following description and accompanying drawings which are given by way of illustration only, and thus are not limitative of the invention, and wherein:

FIG. 1A shows a diagram of a conventional ESD circuit;

FIG. 1B shows the structure of a diode used in an embodiment of the conventional ESD circuit;

FIG. 1C shows the structure of a diode used in another embodiment of the conventional ESD circuit;

FIG. 2A shows a diagram of the disclosed ESD circuit with an ESD zener diode; and

FIG. 2B shows the structure of the ESD zener diode in FIG. 2A.

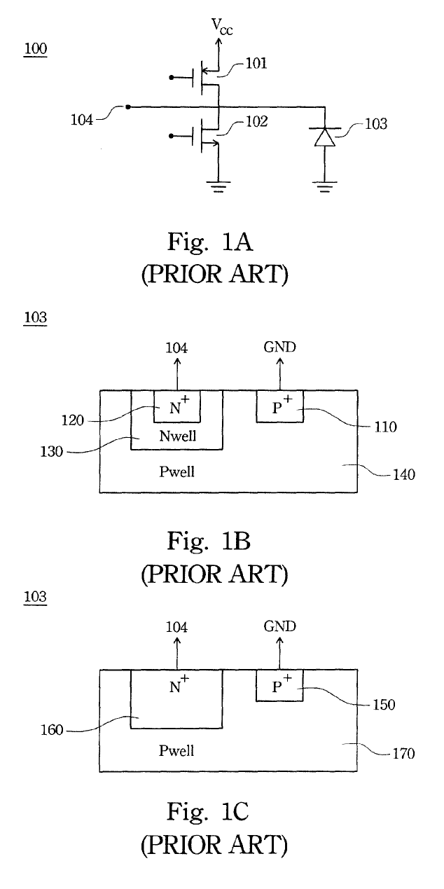

### DETAILED DESCRIPTION OF THE INVENTION

The present invention will be apparent from the following detailed description, which proceeds with reference to the accompanying drawings, wherein the same references relate to the same elements.

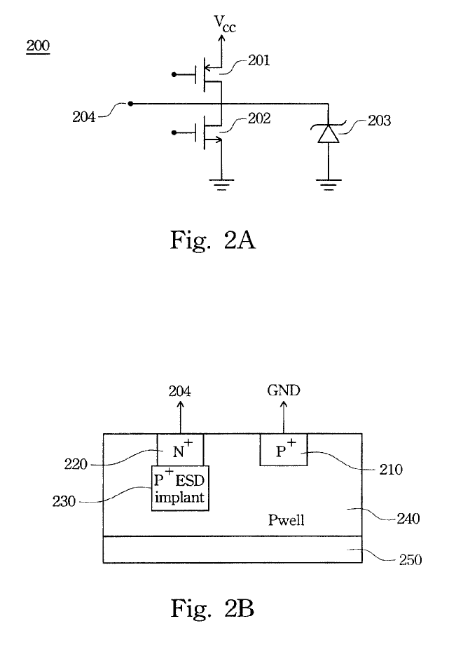

A preferred embodiment of the disclosed ESD circuit 200 is shown in FIG. 2A. The circuit 200 includes an NMOS transistor 202, a PMOS transistor 201, and an ESD zener diode 203. The source of the PMOS transistor 201 is coupled to a high voltage Vcc. The drain of the NMOS transistor 202 is simultaneously coupled to a circuit device terminal 204, the drain of the PMOS transistor 201, and the cathode of the ESD zener diode 203. The anode of the ESD zener diode 203 is coupled to the ground. When a normal positive voltage Vcc is imposed on the NMOS transistor 202 and the PMOS transistor 201, the NMOS transistor 202 and the PMOS transistor 201 are electrically coupled. However, if the transistor malfunctions or static electricity is produced, the high voltage is discharged via the ESD zener diode 203 without going through the NMOS transistor 202. Therefore, the NMOS transistor 202 is not damaged by the abnormal voltage or static electricity. More explicitly, when an abnormal reverse bias or static electricity discharge occurs to the NMOS transistor 202, most of the reverse current flows through the ESD zener diode 203 to discharge, thereby protecting the NMOS transistor 202 from being damaged by an excessively large reverse voltage.

FIG. 2B shows the structure of the ESD zener diode 203 in FIG. 2A. In the ESD zener diode 203, a P well 240 is first formed on the substrate 250 to build the ESD zener diode 203. Afterwards, the P well 240 is doped to form a P+ doping region 210 and an N+doping region 220. The ESD P+ doping region 230 is formed underneath the N+ doping region 220. The N+ doping region 220 is coupled to the circuit device terminal 204 in FIG. 2A. The P+ doping region 210 is coupled to the ground in FIG. 2A.

The implanted ESD P+ doping region 230 has Group 3A elements such as B, Al, Ga, In, and Tl, and is used to form an ESD zener diode 203 with the N+ doping region 220. This can greatly reduce the breakdown voltage. When used in an ESD circuit 200, it can prevent the circuit from being damaged by abnormal voltages and provides high-voltage electrostatic discharge protection.

According to the preferred embodiment, the invention has the following advantages. In the ESD circuit, the ESD zener diode is used to lower the breakdown voltage down to 5.5-6.5 V. The current can be discharged via the circuit with the ESD zener diode, thereby preventing the circuit from burning out and improving the electrostatic protection function.

While the invention has been described by way of example and in terms of the preferred embodiment, it is to be understood that the invention is not limited to the disclosed embodiments. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. An electrostatic discharge (ESD) device coupled to a circuit device terminal, comprising:
a PMOS transistor, whose source is coupled to a high voltage;
an NMOS transistor, whose drain is coupled simultaneously to the drain of the PMOS transistor and the circuit device terminal and whose source is coupled to a ground; and
an ESD zener diode, whose cathode is coupled to the circuit device terminal and whose anode is coupled to the ground.

2. The device of claim 1, wherein the breakdown voltage of the ESD zener diode is between 5.5 V and 6.5 V.

3. The device of claim 1, wherein the ESD zener diode comprises:
a substrate;
a P well in the substrate;
a P+ doping region on the surface of the P well for coupling to the ground;
an N+ doping region on the surface of the P well for coupling to the circuit device terminal; and
a P+ESD doping region coupled next to the N+ doping region for forming an N+-P+ junction with the N+ doping region.

4. The device of claim 3, wherein the P+ doping region is doped with a Group 3A element.

5. The device of claim 4, wherein the P+ doping region is doped with B.

6. The device of claim 4, wherein the P+ doping region is doped with Al.

7. The device of claim 4, wherein the P+ doping region is doped with Ga.

8. The device of claim 4, wherein the P+ doping region is doped with In.

9. The device of claim 4, wherein the P+ doping region is doped with Tl.
